(19) United States
(12) Patent Application Publication
(10) Pub. No.: US 2011/0313576 A1
(43) Pub. Date: Dec. 22, 2011

(54) SYSTEM AND METHOD FOR FLOWING FLUIDS THROUGH ELECTRONIC CHASSIS MODULES

(76) Inventor: MARK RANDAL NICEWONGER, Mountain View, CA (US)

(21) Appl. No.: 13/163,329

(22) Filed: Jun. 17, 2011

Related U.S. Application Data
(60) Provisional application No. 61/356,016, filed on Jun. 17, 2010.

(51) Int. Cl. G05D 7/06; G05D 23/19; F15D 1/00; H05K 7/20

(52) U.S. Cl. 700/282; 361/689; 361/699; 361/701; 137/15.01; 137/343

(57) ABSTRACT

An electronic chassis distributes fluids to adjacent chassis and electronic modules housed within the chassis. Provision is made for the detection, containment, and removal of liquid spilled within the chassis. The fluids may be used as coolants, and provision is made for heat exchanger modules to be included within the chassis. Provision is further made to include fluid sensors and actuators, allowing for monitoring and control of fluid distribution by a controller.

### CROSS-REFERENCE TO RELATED APPLICATIONS

This application claims priority to: 1) United States provisional application, Ser. No. 61/356,016, filed Jun. 17, 2010, which application(s) are all also incorporated by reference herein in their entirety.

### FIELD OF TECHNOLOGY

This disclosure relates generally to the technical fields of routing fluids, and in one example embodiment, this disclosure relates to a method, apparatus and system of distributing fluids through interchangeable modules.

### BACKGROUND

1. Technical Field

The present invention relates to the distribution of fluids to electronic equipment. Such equipment generally includes computers, communications equipment, and data storage devices. The electronic circuits of such equipment are typically housed either directly within a chassis, or within a second sub-chassis module fitting into a main chassis. The chassis are often mounted into an equipment rack, the standard 19-inch rack being commonly employed. Fluids distributed to electronic equipment are typically used as a coolant for removing heat generated by the electronic circuits. The most commonly used coolant is air, but liquid coolants such as water are also employed, especially in applications where high amounts of heat are being generated in a compact space (high heat density). There is a movement in the computing industry toward increasing cooling system efficiency by close-coupling of liquid coolants, bringing the liquid coolant as close as possible to the source of the heat.

2. Background of the Invention

A large body of art exists relating to the direct application of liquid coolants to electronic circuits and components. However, direct liquid cooling has not been widely adopted in practice, largely due to difficulties encountered in the mechanics of delivering liquids to the great number of circuits often packed within the constrained space of an equipment rack. In the limited cases where electronic circuits are being directly cooled by liquids, distribution manifolds for coolant supply and return are often fitted to the equipment rack, and each electronic module within the rack connected to the manifolds by flexible tubing (rubber hose). Even when the flexible tubing is equipped on at least one end with a quick-disconnect type of fitting, servicing such a system can be difficult, and the risk of liquid leaks and spills reaching the electronic circuits is considered too high for adoption in most applications. Consider for example, direct liquid cooling in a blade-server application with eighty-four servers housed in a standard 19-inch equipment rack. With two rubber hoses connected to each server (one for coolant supply, and one for return), the equipment rack would need to accommodate a total of one-hundred and sixty-eight hoses, with three-hundred and thirty-six connection points, far too many to be practically implemented and maintained. A leak or spill at a single point could jeopardize the operation of the entire rack of eighty-four servers.

### SUMMARY OF THE INVENTION

The objective of the present invention is to create a simple, safe, effective and reliable system for distributing liquid coolants for close-coupled cooling of electronic components housed within an equipment rack. The present invention specifically addresses the transmission of a liquid coolant loop from its point of entry into an equipment rack, to its point of entry into an electronic module within the rack. The art of applying liquid coolant directly to electronic components, or distributing liquid coolant throughout a facility is outside the scope of the present invention.

The present invention accomplishes this objective in three parts:
1. The integration of fluid flow channels into an electronic chassis in such a way that multiple chassis can fit together in a modular fashion to create a fluid distribution system for an entire rack of electronic equipment.
2. A fluid connection system that allows electronic equipment modules to make a direct fluid connection to the fluid distribution system without the need for connecting hoses.
3. A liquid spill detection and containment system that can:
   a. detect a coolant leak,
   b. provide information to indicate the location and relative magnitude of the leak,
   c. localize the leak to prevent spilled coolant from unduly affecting the bulk of equipment in the rack,
   d. provide a means of safely removing spilled coolant from the rack before it can reach surrounding equipment.

The invention is suitable not only for delivering coolant to electronic equipment, but also for supporting auxiliary equipment such as heat exchangers in close proximity to the electronic equipment. It may also be embellished by the addition of fluid sensors and actuators to allow for measurement and control of the fluid distribution. While the present invention is particularly suited for use with liquid coolants, it can accommodate any fluids, and may therefore be applied with the use of two-phase coolants, or to any other application involving fluids in close proximity to electronic equipment.

The methods, systems, and apparatuses disclosed herein may be implemented in any means for achieving various aspects of the present disclosure. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 depicts a rear view of an open-frame electronic chassis with two fluid flow channels on the back of the chassis for distributing fluid among adjoining chassis, and fluid connection ports for direct fluid communication to a server module, in one or more embodiments.

FIG. 2A depicts a cross-sectional view of a normally-closed fluid shut-off mechanism to prevent fluids from being lost when a module is removed from a chassis.

FIG. 2B depicts a cross-sectional view of the fluid shut-off mechanism in the open position when the module is in the operational position.

FIG. 3 depicts adjoining chassis fitting together to form two continuous fluid flow passageways traversing an equipment rack.

FIG. 4A depicts a cut-away view of an electronic chassis with two fluid flow channels being integral to the chassis, and a third channel for draining liquid spills.

FIG. 4B depicts a cross-sectional view of a branch drain passageway for collecting liquid spills from the drip pan of an adjoining chassis above.

FIG. 5 depicts a heat exchanger application where fluid flow passageways serve as a coolant loop for an array of air-to-liquid heat exchanger modules.

FIG. 6 depicts a cut-away view of a liquid-to-liquid heat exchanger in which two additional fluid flow channels are integrated into the chassis to create a second coolant loop.

FIG. 7A depicts a plurality of interconnected electronic controllers to collaboratively assess and control the operational conditions of the fluid distribution system.

FIG. 7B depicts a block diagram of the electronic control system.

FIG. 8 depicts a cut-away view of a blade server application with parallel coolant sub-loops within a chassis.

Other features of the present embodiments will be apparent from the accompanying drawings and from the detailed description that follows.

### DETAILED DESCRIPTION

A preferred embodiment of the invention would be for the purpose of cooling servers, where each server module is individually housed in a chassis having a 1U form. The chassis provides a coolant loop for cooling the server CPU and other electronic components such as communications or data storage devices within the module. The chassis can alternately house heat exchanger modules for transferring heat between coolant loops, or airborne heat to a coolant loop. The coolant in this embodiment is a liquid, or in alternate embodiments the module may implement a two-phase cooling system where the coolant entering the module is a liquid and the coolant exiting is a gas, or mixture of gas and liquid. Multiple coolant loops can be implemented with differing coolants employed for each loop. Multiple chassis are placed into a standard 19-inch equipment rack, with the liquid coolant loop interflowing between adjoining chassis.

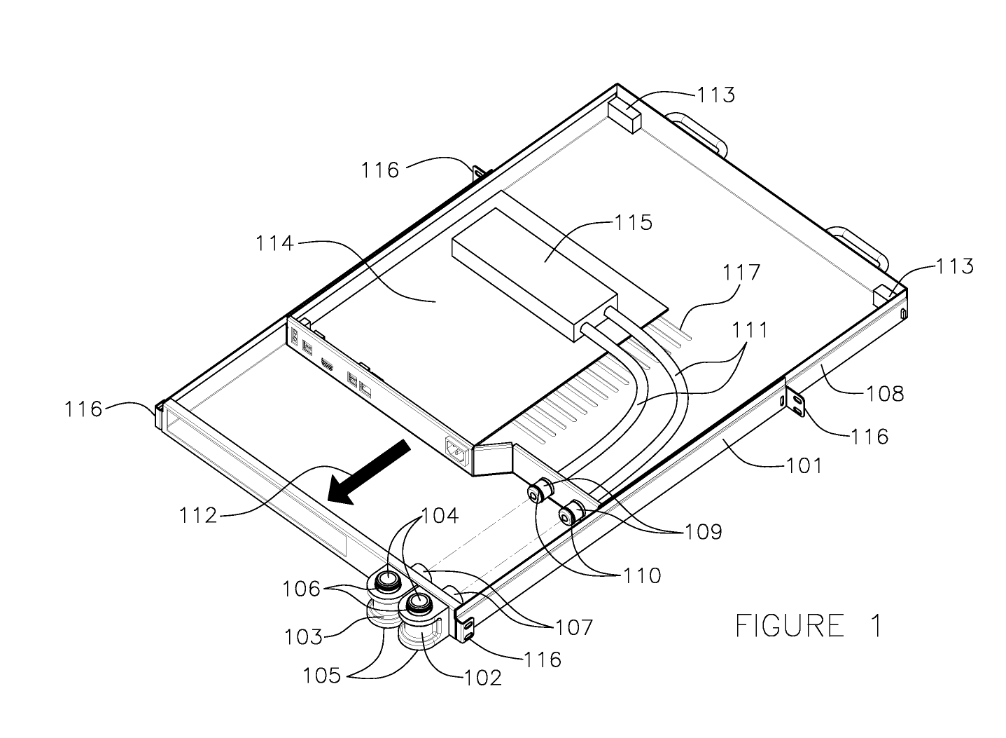

FIG. 1 illustrates a rear view of one such embodiment, with an open-frame chassis (101), open on the top and front, and a corresponding server module (108). The chassis provides a first fluid flow channel (102) for coolant supply and a second fluid flow channel (103) for coolant return. The fluid flow channels are attached to the back, extending from the top to bottom of the chassis. Each channel is fitted with a male fluid interconnection port (104) at one end, and a female fluid interconnection port (105) at the opposite end. The male fluid interconnection ports are fitted with rubber o-rings (106). Each channel is additionally fitted with a perpendicularly aligned female fluid connection port (107) extending through the back of the chassis for the purpose of connecting to a server module (108). Male fluid connection ports (109), fitted with rubber o-rings (110), protrude from the server module, and constitute the coolant supply and return for the module's internal coolant loop, which is further comprised by tubing sections (111) connecting to a cold plate (115) mounted to the server motherboard (114). As the server module is inserted into the operational position from the front of the chassis as indicated by the action arrow (112), the male fluid connection ports (109) fit into the corresponding female fluid connection ports (107) of the chassis fluid flow channels (102 and 103), thus forming leak-tight fluid connections between the module's coolant loop and the fluid flow channels. A releasable latch (113) secures the module in the operational position within the chassis. Mounting brackets (116) at each corner of the chassis hold the chassis in the rack. Openings (117) in the bottom of the module allow liquids that may leak or otherwise escape within the module to exit.

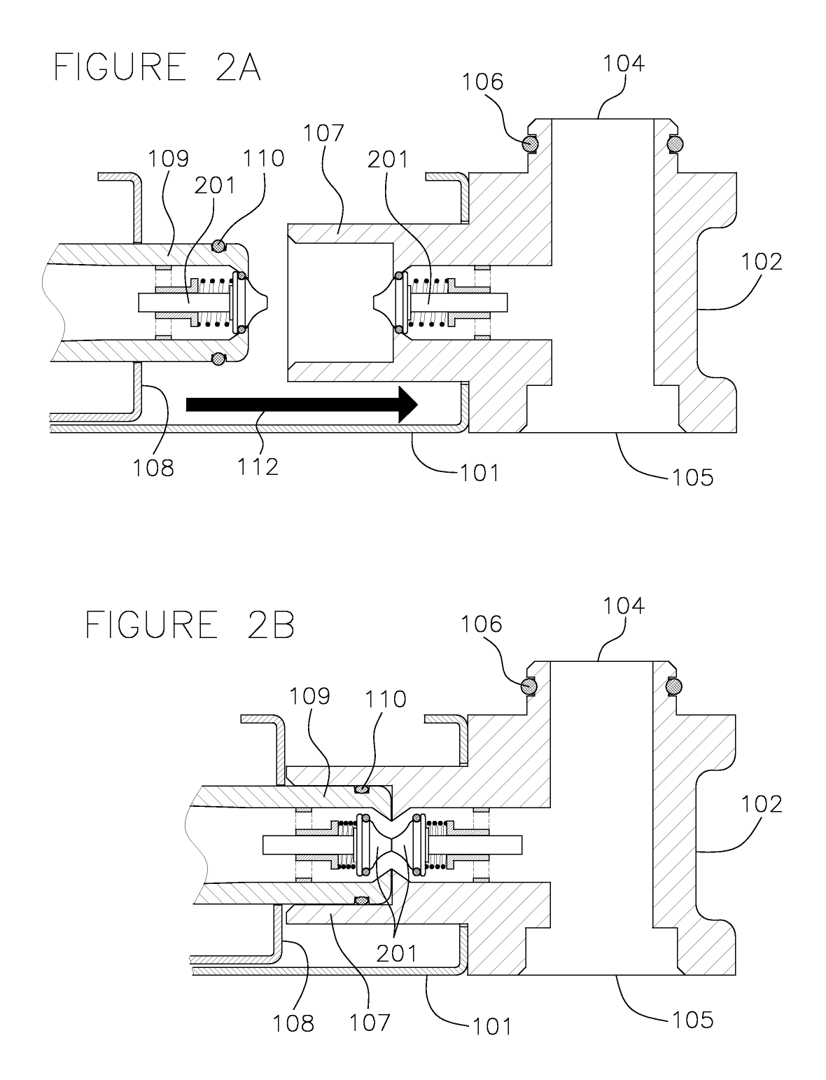

As further illustrated in the cross-sectional diagram of FIGS. 2A and 2B, both the chassis fluid connection port (107) and module fluid connection port (109) are internally fitted with normally-closed fluid shut-off valves (201). The act of inserting the module (108) into an operational position, as illustrated in FIG. 2A by the action arrow (112), actuates a mechanism to move the valve diaphragms to their open position as shown in FIG. 2B, thus allowing coolant to flow through the module's internal coolant loop. In like manner other elements such as electronically actuated valves, fluid flow sensors and fluid temperature sensors may be alternately or additionally added to either the chassis or module connection ports. Other elements (101, 102, 104, 105, 106, and 110) of FIGS. 2A and 2B are as previously described for FIG. 1.

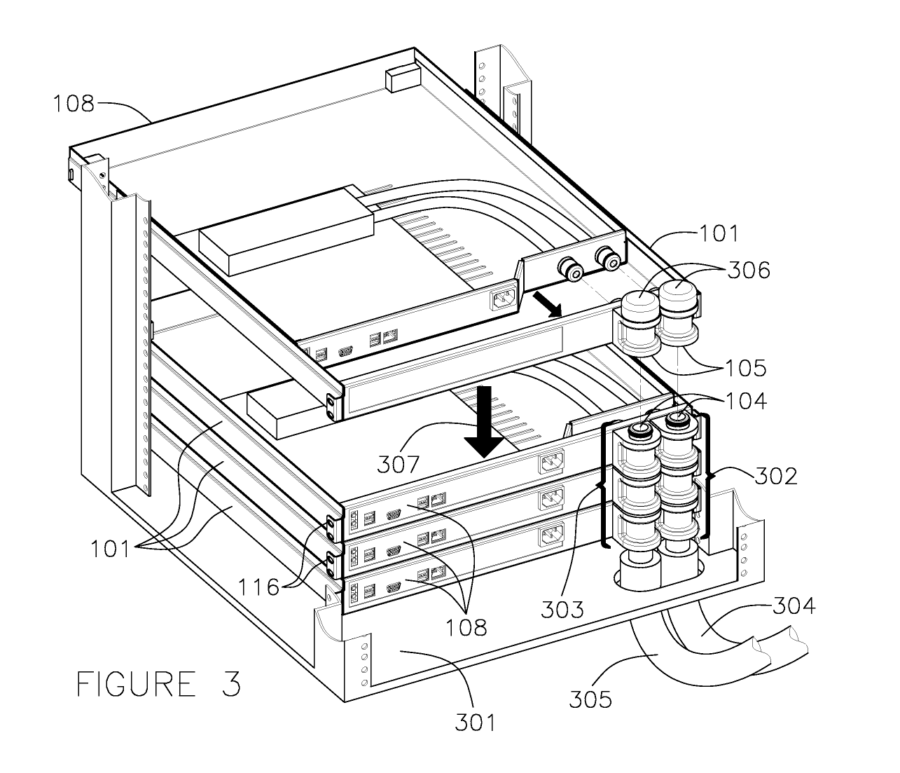

FIG. 3 illustrates a rear view of a plurality of chassis (101) being joined together as they are inserted into a 19-inch equipment rack (301). After the first chassis is installed at the bottom of the rack, the succeeding chassis are initially inserted into the rack slightly above their operational position, and then lowered to their final operational position as indicated by the action arrow (307). As the second and succeeding chassis are installed, female fluid interconnection ports (105) of each chassis fit into the male fluid interconnection ports (104) of the adjoining chassis below, thus achieving a leak-tight connection between the fluid channels of adjoining chassis. The chassis are secured in their operational position by mounting brackets (116) at each corner. Once a chassis is in place, it is ready to receive a server module (108).

Continuing with FIG. 3, as delineated by brackets (302 and 303), two continuous fluid passageways are formed running from bottom to top of the rack as the chassis are installed into their operational positions. One of the continuous passageways (302) is used to supply coolant to a plurality of server modules (108) inserted into the plurality of chassis, and the second passageway (303) is used to return coolant from the server modules, thus comprising multiple coolant loops in parallel. An external coolant loop supply (304) and return (305) is connected by rubber hoses to the bottom end of the continuous fluid passageways, with the opposite ends of the fluid flow passageways terminated by leak-tight caps (306). The external coolant loop supply and return may alternately be connected to the top of the continuous fluid passageways, with leak-tight plugs at the bottom.

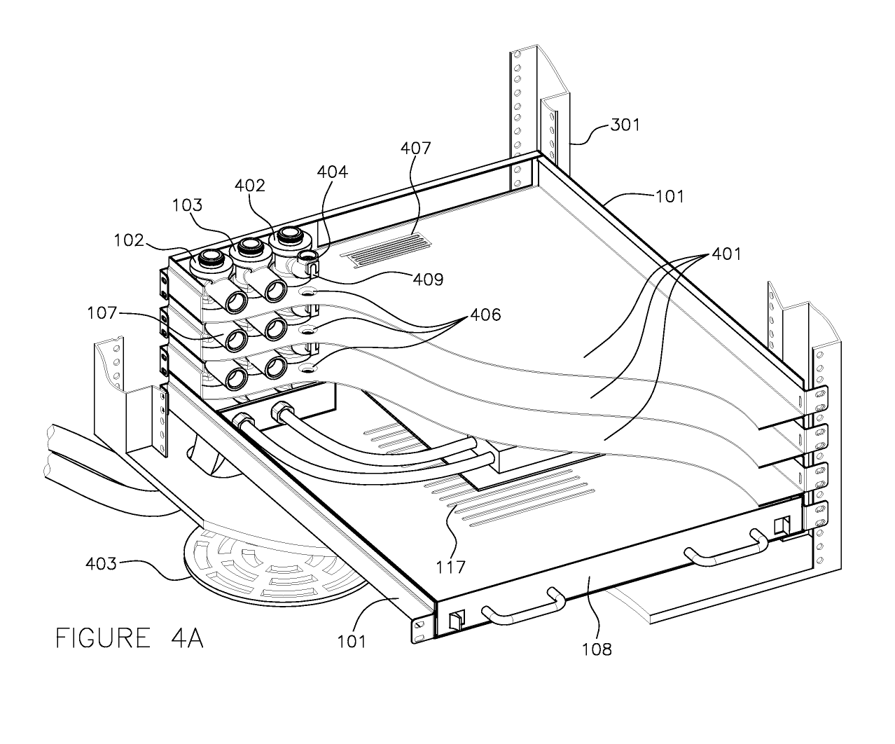

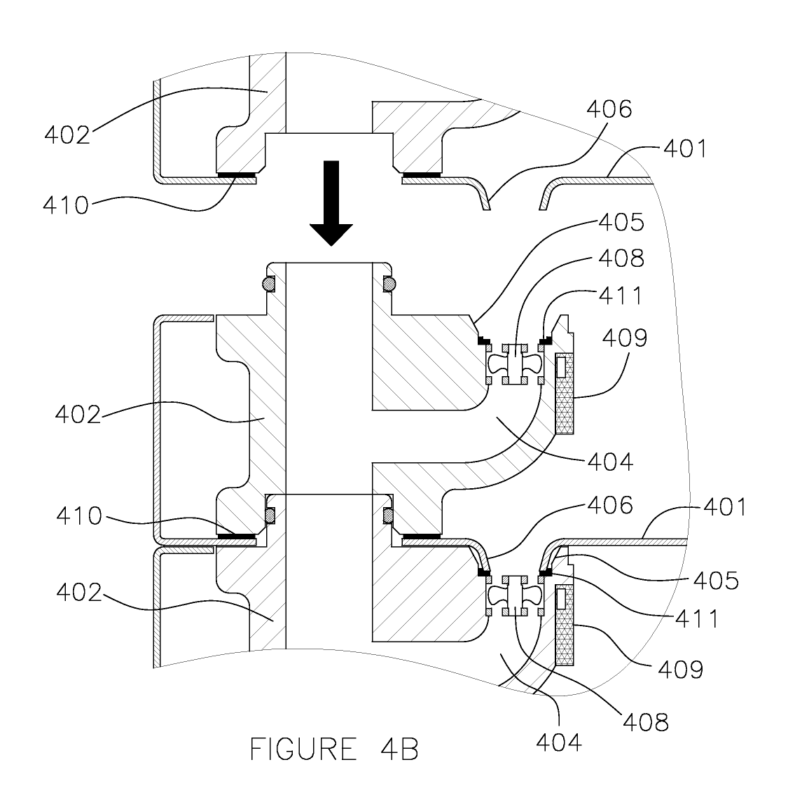

In a further preferred embodiment of the chassis (101), illustrated in the cut-away drawing of FIG. 4A, the bottom of the chassis forms a liquid drip pan (401). The fluid flow channels (102 and 103) are placed within the perimeter of the pan, so liquid from leaks that may occur in the fluid flow passageways are collected in the pan, as well as liquid from leaks that may occur in any inserted module (108) or at the fluid connection ports (107). Openings (117) in the bottom of the server module (108) allow leaks originating within the module to reach the drip pan. A drain opening (406) and a third fluid flow channel (402) are added to the chassis to provide a drain passageway for liquids collected in the liquid drip pan. The drain channel includes a branch fluid flow channel (404) to collect liquid from the drain of the adjacent chassis above. Liquids flow through the drain channel by force of gravity to a floor drain (403) or collection reservoir beneath the rack (301). The bottom of the drip pan is fitted with a moisture detection sensor (407). The branch fluid flow channel is fitted with a Hall-effect sensor (409) that works in conjunction with a turbine disposed within the branch fluid flow channel to constitute a fluid flow sensor.

As further illustrated in the cross-sectional view of FIG. 4B, the drain channel (402) is fitted with a branch fluid flow channel (404) that terminates in a female fluid connection port (405) with a rubber gasket (411) near the top of the enclosure. The drain (406) channels spilled liquids from the drip pan (401) to the connection port (405) of the branch channel (404) of the adjoining chassis beneath, and thus into the drain passageway (402). A second gasket (410) prevents liquid from leaking at the junction of the fluid flow channel and the drip pan. The branch fluid flow channel is fitted with a fluid flow sensor comprising a turbine (408) and Hall-effect sensor (409).

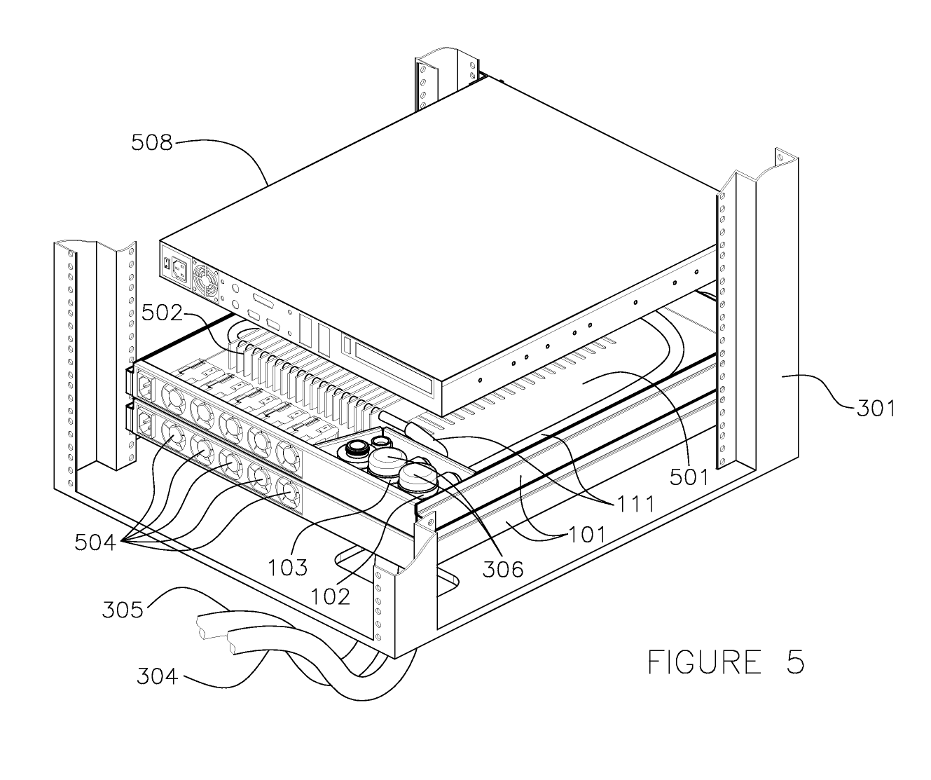

As shown in FIG. 5, an alternate embodiment of a module (501) inserted into a chassis (101) functions as an air-to-liquid heat exchanger. The module circulates air from back to front of an enclosed equipment rack (301) to remove heat generated by air-cooled equipment installed in the rack, such as an air-cooled server (508) or power supply. Airborne heat is transferred to the radiant heat exchanger core (502), which along with tubing sections (111) constitutes the coolant loop of the heat exchanger module. This coolant loop is further extended by the chassis fluid flow channels (102 and 103), which connect to the external coolant loop supply (304) and return (305), and are capped (306) at the opposite end. Fans (504) at the rear of the heat exchanger module draw warm air from the back of the rack, and exhaust cooled air to the front of the rack. A plurality of heat exchanger modules are installed into the rack, thus making the cooling system scalable and providing failsafe redundancy.

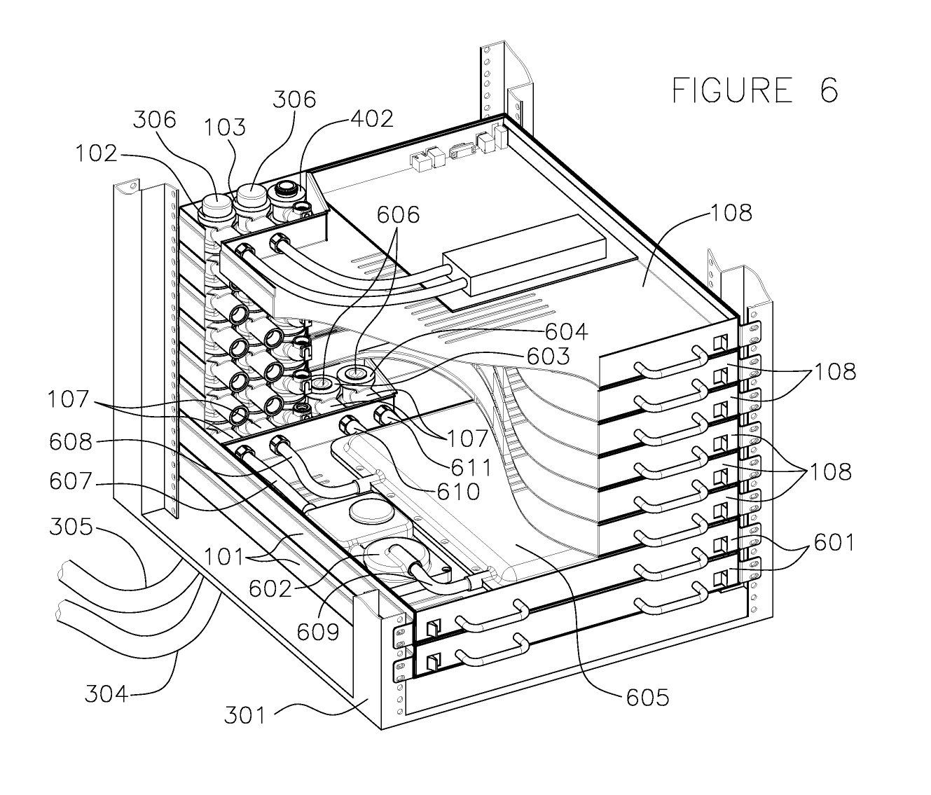

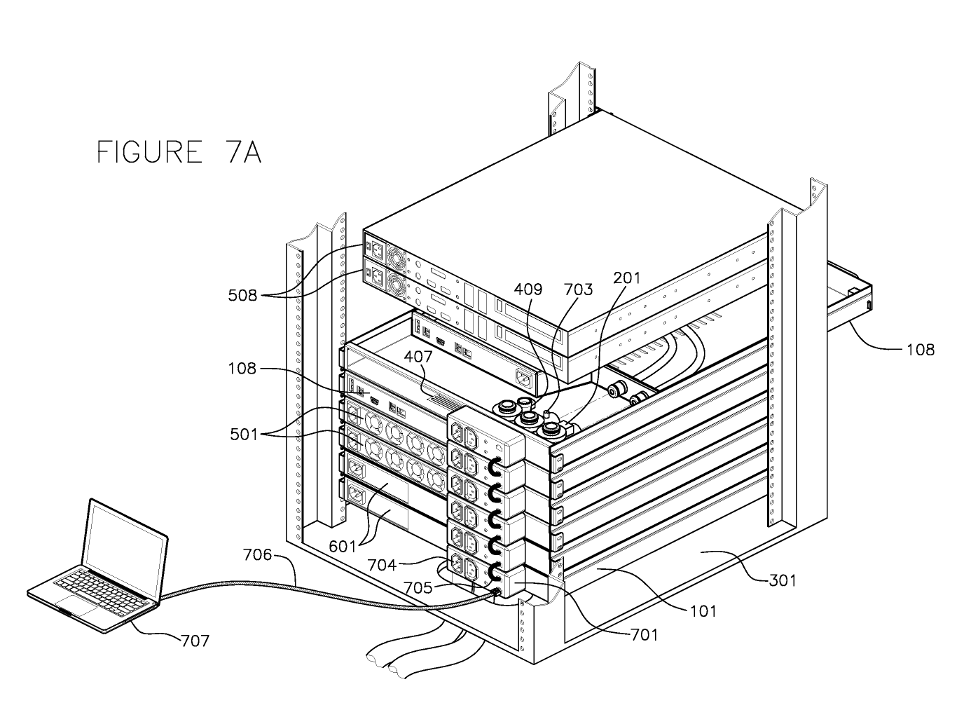

Yet another form of module, shown in the cut-away drawing of FIG. 6, is a liquid-to-liquid heat exchanger. A first coolant loop comprises at least one heat exchanger module (601) and a first set of fluid flow channels (102 and 103) that circulate coolant to at least one server module (108). Within the heat exchanger module the first coolant loop further comprises, a first supply coolant tubing section (607), a first return coolant tubing section (608), a connecting tubing section (609), a heat exchanger core (605) and coolant pump (602) to circulate coolant through the entire loop. The first coolant loop is interconnected only within the confines of the rack, and thus both ends of the two continuous fluid flow passageways are terminated with caps (306). The heat exchanger chassis (101) additionally provide a second coolant loop in fluid isolation from the first coolant loop, comprising a second set of fluid flow channels (603 and 604) connected only to the heat exchanger modules. An external facilities supply (304) and return (305) circulates coolant through the second coolant loop, with the opposite ends of these two fluid flow passageways terminated with plugs (606). Within the heat exchanger module, the second coolant loop further comprises a second supply coolant tubing section (610), and a second return coolant tubing section (611) connected to the heat exchanger core (605). The heat exchanger core (605) is common to both the first and second coolant loops, and transfers heat from the first coolant loop to the second coolant loop. The heat exchanger module is fitted with four male fluid connection ports that insert into the chassis fluid connection ports (107) to provide fluid communication between the module and the two coolant loops. A plurality of heat exchanger modules results in multiple pumps (602) being interconnected in parallel to deliver coolant to a common first coolant loop, thus making the cooling system scalable and providing failsafe redundancy. All chassis are equipped with a drainage system (402) as previously described.

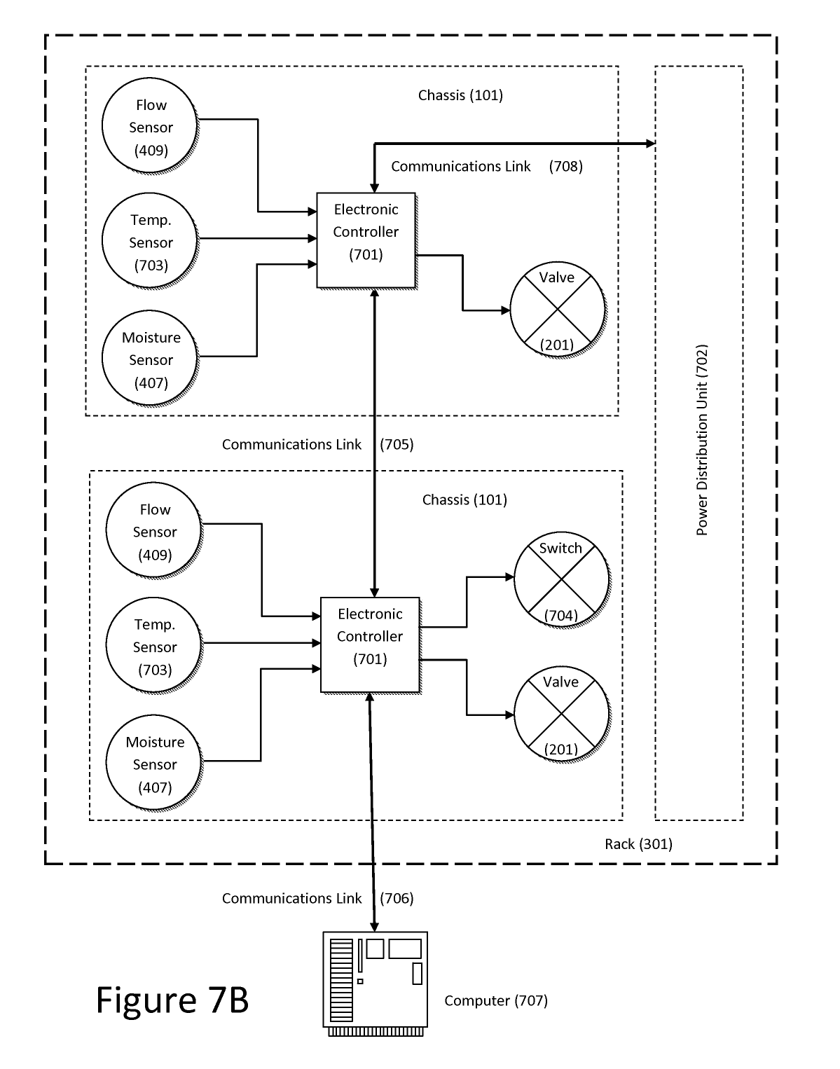

In FIG. 7A, an electronic controller (701) is attached to each chassis (101) to receive signals from fluid flow rate sensors (409), fluid temperature sensors (703), and moisture sensors (407) disposed within the chassis, as further illustrated in the block diagram of FIG. 7B. The combination of sensors allows the controller to differentiate between a small liquid spill presenting no immediate threat to the servers, and a dangerous leak requiring immediate shut off of the coolant. The electronic controller is also interconnected to an electrically actuated fluid shut-off valve (201) disposed in fluid communication with the coolant supply port, thus allowing coolant flow to be shut off in response to a severe leak. The coolant return would correspondingly be automatically shut off by a check valve within the coolant return port. The controller also includes an electronically switched AC power outlet (704) to cut power to the server module, or alternately communicates via a communications link (708) with an external power distribution unit (702) to cut power in response to a dangerous leak. The electronic controller comprises a processing unit with at least one communications link (705) interconnected with at least one other controller disposed to the plurality of chassis (101) housed within the rack (301). Thus the plurality of controllers can collaboratively assess and respond to the liquid distribution system's operational conditions, for example to determine the location and severity of a leak. The controllers can singularly or collectively assess fluid operational conditions such as the heat load of one or more server modules, and accordingly respond with appropriate actions such as the adjustment of coolant flow rate to attain optimal energy efficiency. The electronic controller employs a communication link (706) to transmit information pertaining to the fluid distribution system's operational conditions to an outside computer (707).

FIG. 7A further demonstrates that a rack (301) populated with a plurality of chassis (101) may accommodate a combination of water-cooled server modules (108), air-cooled servers (508), air-to-liquid heat exchanger modules (501), and liquid-to-liquid heat exchanger modules (601). In this embodiment, only the bottom two chassis include all five fluid flow passageways, with the fourth and fifth fluid flow passageways connecting the facilities coolant loop only to the liquid-to-liquid heat exchanger modules (601), which are thus limited to the bottom two chassis. The remaining three fluid flow passageways pass through all chassis, comprising the coolant loop and drain passageway for the server modules and air-to-air heat exchanger modules. Although these modules make no fluid connection to the facilities coolant loop, they alternately could be designed to fit into a chassis having all five fluid flow passageways, thus allowing the rack to be wholly populated with five-passageway chassis, permitting liquid-to-liquid heat exchanger modules to be disposed to any chassis in the rack, and the air-to-liquid heat exchanger modules to be alternately connected to the facilities coolant loop.

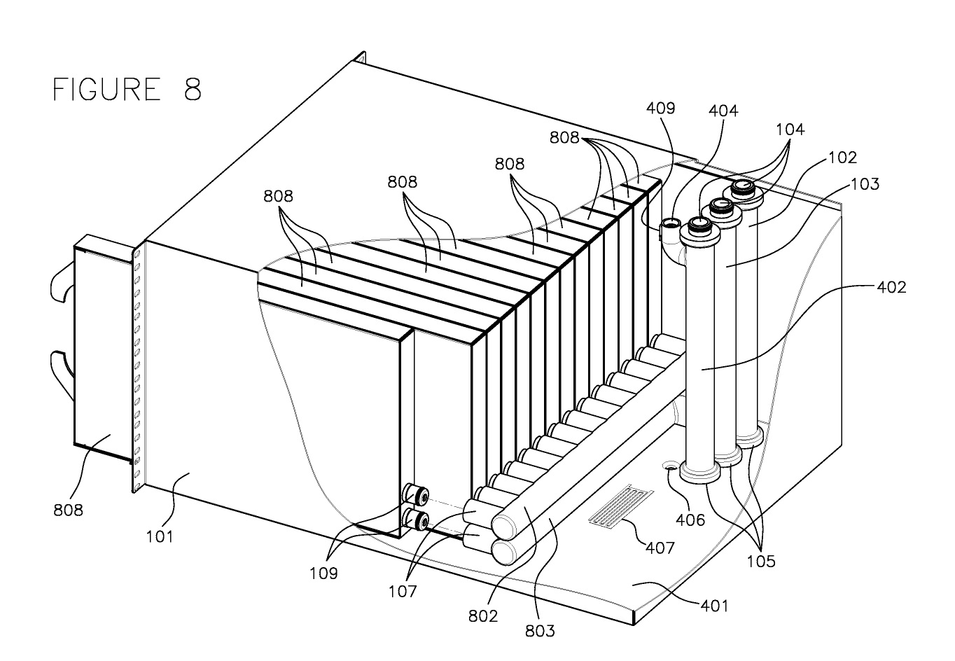

An alternate embodiment of the chassis (101), as shown in FIG. 8, would have a 7U form to accommodate a plurality of blade server modules (808). In this embodiment, the fluid channels for coolant supply (102) and return (103) further comprise second fluid channels (802 and 803), perpendicularly oriented within the chassis. The each of the second channels is fitted with a plurality of female fluid connection ports (107). In the same manner as previously described for a server module inserted into a 1U chassis, the blade server modules (808) are fitted with male fluid connection ports (109) that fit into the female fluid connection ports (107) to form a leak-tight seal when the server modules are inserted into an operational position. Both the server fluid connection ports and second channel connection ports are internally fitted with fluid shut-off valves as previously described for the 1U chassis. The chassis is fitted with a drip pan (401), drain (406), moisture detection sensor (407) and drainage channel (402) with a branch channel (404) and fluid flow sensor (409) as previously described. The chassis fluid channels retain the previously described male fluid interconnection port (104) at one end, and a female fluid interconnection port (105) at the opposite end, providing the means of coupling to the fluid channels of adjoining chassis.

The invention has been described in a preferred embodiment of delivering coolant to rack-mounted servers, but can also be employed in cooling other electronic devices such as telecommunication equipment. The invention can provide flexibility, scalability and ease of configuration for many other applications where fluids are used in proximity to electronic equipment, and thus the invention is not limited to cooling systems. Other embodiments might include: (a) fluid dispensing systems, where for example rack-mounted equipment dispenses metered amounts of various process gasses to semiconductor deposition equipment, or fluids to wafer cleaning equipment, (b) fire suppression systems, where controlled amounts of Halon gas are delivered to equipment in response to fire, (c) rack-mounted pneumatic or hydraulic control systems, (d) complex fluid handling and multiplexing systems for pharmaceutical production or medical or scientific research, and many other applications as may be effected by those skilled in the art.

While the invention has been described in detail herein in accordance with certain preferred embodiments thereof, many modifications and changes therein may be effected by those skilled in the art. For example, methods and operations described herein can be in different sequences than the exemplary ones described herein, e.g., in a different order. Thus, one or more additional new operations may be inserted within the existing operations or one or more operations may be abbreviated or eliminated, according to a given application, so long as substantially the same function, way and result is obtained. Accordingly, it is intended by the appended claims to cover all such modifications and changes as fall within the true spirit and scope of the invention.

What is claimed is:

1. A method of conducting fluid between adjoining electronic equipment chassis, comprising:
(a) disposing to each chassis at least one discrete fluid flow channel directly spanning opposing outermost planes of the chassis, whereby fluid is conducted between opposing external spaces in isolation from the internal airspace of the chassis,
(b) including a means of removably coupling at least one end of at least one fluid flow channel directly to at least one corresponding fluid flow channel of at least one adjoining chassis,
(c) intercoupling corresponding discrete fluid flow channels of adjoining chassis, whereby the combination of discrete fluid flow channels forms at least one continuous discrete fluid flow passageway traversing the totality of adjoining chassis.

2. A method as in claim 1, of further conducting fluid to at least one equipment module disposed within at least one chassis, comprising:
(a) including at least one fluid communication port perpendicular to and in fluid communication with at least one discrete fluid flow channel, whereby the combination of intercoupled discrete fluid flow channels and corresponding fluid communication ports constitutes at least one discrete fluid manifold and corresponding manifold ports,
(b) connecting at least one fluid manifold port in fluid communication to at least one module disposed within at least one of the adjoining chassis.

3. A method as in claim 1, of further conducting escaped liquid within the chassis, comprising:
(a) including at least one liquid drip pan within at least one chassis,
(b) including at least one drain at the bottom of the drip pan,
(c) including at least one branch fluid flow channel within at least one chassis, with a first end in fluid communication with at least one discrete fluid flow channel, and a second end extending upward to provide a means of removably coupling for fluid communication directly to at least one drain of at least one liquid drip pan of an adjoining chassis above,
(d) intercoupling the corresponding discrete fluid flow channels of adjoining chassis, whereby the combination of discrete fluid flow channels forms at least one continuous discrete drain passageway traversing the totality of adjoining chassis,
(e) intercoupling the corresponding branch fluid flow channel and drip pan drain, whereby escaped liquid captured in the drip pan flows from the drip pan, through the branch fluid flow channel, into the drain passageway.

4. An apparatus for conducting fluid between adjoining electronic equipment chassis, comprising:
an electronic chassis, wherein the chassis includes at least one discrete fluid flow channel directly spanning opposing outermost planes of the chassis, whereby fluid is conducted in isolation from the internal airspace of the chassis, wherein at least one end of the discrete fluid flow channel includes a means of removably coupling directly to a corresponding discrete fluid flow channel of an adjoining chassis.

5. An apparatus as in claim 4, for further conducting fluid to at least one equipment module, in which at least one discrete fluid flow channel includes at least one fluid connection port in fluid communication with at least one equipment module disposed within the chassis.

6. An apparatus as in claim 5, in which the module is removably coupled to the fluid connection port, whereby insertion of the module into an operational position establishes fluid communication between the fluid flow channel and the module.

7. An apparatus as in claim 6, in which the fluid connection port and inserted module include at least one fluid control valve with an operating mechanism, whereby the valve is automatically operated in response to insertion and removal of the module.

8. An apparatus as in claim 6, in which the inserted module includes a releasable latching mechanism, whereby the module is secured into an operational position within the chassis.

9. An apparatus as in claim 5, in which at least one equipment module and a plurality of discrete fluid flow channels constitute at least one coolant loop.

10. An apparatus as in claim 4, in which the chassis includes at least one liquid drip pan with at least one drain, and at least one discrete fluid flow channel includes at least one branch fluid flow channel extending upward to provide a means of removably coupling for fluid communication directly to at least one drain of at least one liquid drip pan of an adjoining chassis above.

11. An apparatus as in claim 5, in which the chassis includes at least one electronic controller and at least one fluid flow sensor, fluid temperature sensor, moisture detection sensor, electrical power measurement sensor, electrically-operated fluid control valve or electrically-operated electrical switch, wherein the electronic controller is in electrical communication with at least one sensor and at least one valve, switch or external power distribution unit, whereby the controller determines the occurrence of a liquid leak and responsively shuts off coolant flow or electrical power to at least one module, or varies the rate of coolant flow to at least one module in response to a temperature or power measurement.

12. An apparatus as in claim 11, in which the electronic controller comprises a digital processor unit and memory for storing a digital control program, which is executed by the processor unit for controlling the module, and at least one communication link for interconnecting the controller and at least one computer or power distribution unit, or interconnecting a plurality of controllers disposed to a plurality of chassis.

13. A system for conducting fluid between electronic equipment chassis, comprising:
a plurality of adjoining electronic chassis, wherein each chassis includes at least one discrete fluid flow channel directly spanning opposing outermost planes of the chassis, whereby fluid is conducted in isolation from the internal airspace of the chassis, with at least one end of the discrete fluid flow channel removably coupling directly to a corresponding discrete fluid flow channel of at least one adjoining chassis, whereby the combination of discrete fluid flow channels forms at least one continuous discrete fluid flow passageway traversing the totality of adjoining chassis.

14. A system as in claim 13, for further conducting fluid to at least one equipment module, in which at least one discrete fluid flow channel includes at least one fluid connection port in fluid communication with at least one equipment module disposed within the chassis.

15. A system as in claim 14, in which the module is removably coupled to the fluid connection port, whereby insertion of the module into an operational position establishes fluid communication between the fluid flow channel and the module.

16. A system as in claim 13, further comprising a liquid leak containment and removal system, in which each chassis includes at least one liquid drip pan with at least one drain, and at least one discrete fluid flow channel includes at least one branch fluid flow channel extending upward to removably couple in fluid communication directly to at least one drain of at least one liquid drip pan of an adjoining chassis above

17. A system as in claim 14, further comprising an equipment cooling system, in which at least one equipment module and a plurality of discrete fluid flow channels constitute at least one coolant loop.

18. A system as in claim 17, in which the module includes at least one electronic device, wherein heat generated by the electronic device is transferred to at least one coolant loop.

19. A system as in claim 17, in which the module includes at least one heat exchanger, wherein airborne heat is transferred to at least one coolant loop.

20. A system as in claim 17, in which the module includes at least one heat exchanger, wherein heat is transferred from a first coolant loop to a second coolant loop.

21. A system as in claim 20, in which the module includes at least one pump in fluid communication with at least one coolant loop, whereby coolant is pumped through at least one second module disposed to any of the adjoining chassis.

22. A system as in claim 14, further comprising a liquid leak detection system, wherein each chassis includes at least one electronic controller, and at least one moisture detection sensor or fluid flow sensor, and at least one electrically-operated fluid control valve or electrically-operated electrical switch, wherein the controller is in electrical communication with at least one sensor, and at least one valve, switch or external power distribution unit, whereby the controller detects the occurrence of a leak and responsively shuts off fluid flow or electrical power to at least one module.

23. A system as in claim 17, further comprising an energy control system, wherein each chassis includes at least one electronic controller, and at least one electrically-operated fluid control valve in fluid communication with at least one coolant loop, and at least one fluid temperature sensor or fluid flow sensor in fluid communication with at least one coolant loop, or electrical power measurement sensor in electrical communication with at least one equipment module, or temperature sensor in thermal communication with at least one electronic component, wherein the controller is in electrical communication with at least one valve and at least one sensor or external power distribution unit, whereby the controller varies the rate of coolant flow to at least one module in response to at least one temperature or power measurement.

24. A system as in claim 14, further comprising a distributed fluid measurement and control system, wherein each chassis includes at least one electronic controller with at least one communication link, and at least one electrically-operated valve or electrical switch, or fluid flow sensor, fluid temperature sensor, or moisture detection sensor, wherein the electronic controller is in electrical communication with at least one valve, sensor, switch or external power distribution unit, and at least one communication link is interconnecting the plurality of electronic controllers and at least one external computer or power distribution unit, whereby the plurality of electronic controllers collaboratively assess fluid operating conditions, and responsively control at least one valve, switch, or external power distribution unit, or communicate information pertaining to the coolant system operating conditions to at least one computer.

25. A system as in claim 13, in which the chassis are mounted in an equipment rack.
